(19) United States
(12) Patent Application Publication
(10) Pub. No.: US 2026/0339223 A1
(43) Pub. Date: Oct. 29, 2026

(54) DEVICE FOR SAMPLING FOR DETERMINING A CORROSION STATE OF A MODULE FOR SEMICONDUCTOR LITHOGRAPHY, ARRANGEMENT AND METHOD FOR DETERMINING A MODULE STATE

(71) Applicant: Carl Zeiss SMT GmbH, Oberkochen (DE)

(72) Inventors: Eric DE LA CHAUX, Kohlberg (DE); Anissa Celina BOUALI, Aalen (DE); Vincent MA JUNYONG, Bad Nauheim (DE)

(21) Appl. No.: 19/712,975

(22) Filed: Jun. 18, 2026

Related U.S. Application Data
(63) Continuation of application No. PCT/EP2024/085241, filed on Dec. 9, 2024.

(30) Foreign Application Priority Data
Dec. 20, 2023 (DE) 10 2023 213 007.6

(51) Int. Cl. G03F 7/00; G01N 1/04; G01N 23/2252

(52) U.S. Cl. CPC G03F 7/70991; G01N 1/04; G01N 23/2252; G03F 7/70891

(57) ABSTRACT

A sampling device (50) for determining a corrosion state of a module (30) for semiconductor lithography has a rinsing device (64) and a sample collector (56). An associated arrangement includes a fluid channel (40) and a releasable connection element (32) for connecting a fluid line to the fluid channel. An interface (42) is formed between the connection element and the module. The arrangement includes a sampling device and has a rinsing device. A sample collector (56) of the device, arranged downstream of the rinsing device in the introduction direction, is at least partially, optionally completely, introduced into the fluid channel (40). An associated method for determining a corrosion state of an interface between a module (30) of a projection exposure system (1,101) and a connection element (32) includes sampling the interface, analysing the sample (70.1) taken, and determining the state of the interface.

### CROSS-REFERENCE TO RELATED APPLICATION

This is a Continuation of International Application PCT/EP2024/085241, which has an international filing date of Dec. 9, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 213 007.6 filed Dec. 20, 2023.

### FIELD

The invention relates to a device for sampling for determining a state of corrosion of a module for semiconductor lithography and to an arrangement having the device and the module. The invention furthermore relates to a method for determining a module state. In particular, the device and the method can be used for a module of a projection exposure apparatus.

### BACKGROUND

Projection exposure apparatuses for semiconductor lithography are subject to extremely stringent requirements in respect of imaging quality in order to be able to produce the desired microscopically small structures as far as possible without defects. In a lithography process or a microlithography process, an illumination system illuminates a photolithographic mask, also referred to as reticle. The light passing through the mask or the light reflected by the mask is projected, with a projection optics unit, onto a substrate (for example a wafer), which is coated with a light-sensitive layer (photoresist) and mounted in the image plane of the projection optics unit, in order to transfer the structure elements of the mask to the light-sensitive coating of the substrate. The requirements in respect of the positioning of the image representation on the wafer and the intensity of the light provided by the illumination system are increased with every new generation, which results in a higher thermal load on the optical elements.

In cases of high thermal load, it may be advantageous for certain modules, for instance force frames, reference frames or optical modules, especially in EUV projection exposure apparatuses (‘EUV’=Extreme UltraViolet), i.e. in apparatuses that are operated with electromagnetic radiation having a wavelength of between 1 nm and 120 nm, in particular at 13.5 nm, to be temperature-controlled through water cooling. In DUV projection exposure apparatuses (‘DUV’=Deep UltraViolet), too, i.e. in apparatuses which are operated with electromagnetic radiation having a wavelength of between 100 nm and 300 nm, water-cooled modules may be used. These modules comprise fluid channels through which temperature-controlled water usually flows, as a result of which the heat is dissipated from the modules. The water is treated and provided by a water conditioning cabinet, with the water conditioning cabinet being connected to the module via fluid lines. At the interfaces to the module, the feed lines and discharge lines are frequently connected via flanges to the fluid channels formed in the module. In this case, the flanges are sealed with sealing elements vis-à-vis sealing surfaces formed in the module and can be closed for transport and/or storage of the modules. A module may have between 1 and 30 or more such interfaces, with the failure of only one interface, for example as a result of a leak, possibly leading to the failure of the entire module and/or of the entire apparatus. Usually, identical interfaces are used in the entire projection exposure apparatus, i.e. for example both in the illumination system and in the projection optics unit.

The specific requirements for materials in the field of EUV lithography and the resulting material pairings for the module and the flange enable or facilitate corrosion, in particular in the region of the interface. In combination with the sometimes strongly corrosion-promoting behavior of the water, for example on account of impurities, the corrosion can be further intensified over the service life, and so corrosion may occur at the boundary surfaces between flange and sealing surface in the interfaces. In some cases, the corrosion may progress to such an extent that the corrosion creeps under the sealing elements, and this may lead to a leak in the interface. In comparison with the use of the modules, the effect may be further intensified by storage of the modules, especially under improper storage conditions.

The state of corrosion in the region of the interface of the modules cannot be determined in the installed state, i.e. with the flange mounted. On account of the sometimes greatly varying and insufficiently known conditions over the service life, it is not possible to predict, for example on the basis of models, the state of corrosion either. A visual inspection of the interface, with the flange being disassembled, can lead to an interface that is still tight despite corrosion remaining leaky when the flange is reassembled. The visual inspection can thus be a destructive inspection in a large number of cases.

This effect is based on the fact that the damage to the sealing surface caused by corrosion may have progressed to such an extent that the interface can no longer be adequately sealed when the flange is reinserted. The corrosion products produced during corrosion damage the sealing surfaces on the one hand but also contribute to the tightness on the other hand. Thus, an already corroded interface may remain tight when unopened for several months or years but may leak after or soon after opening and reassembly. Repairing or reworking the sealing surfaces is generally not possible for technical reasons.

This results in the disadvantage that a large number of modules need to be scrapped on account of the state of corrosion determination despite still having a sufficient service life left. This has a negative effect on the lifetime costs of the projection exposure apparatus.

### SUMMARY

Objects addressed by the present invention include providing a device and an arrangement which eliminates the disadvantages of the prior art described further above. Further objects include specifying a method which allows the state of corrosion of an interface of the module to be determined without disassembly of the flange.

These objects are addressed by a device, an arrangement and a method having the features of the independent claims. The dependent claims relate to advantageous developments and variants thereof.

A device according to one formulation of the invention for sampling for determining a state of corrosion of a module for semiconductor lithography is distinguished by the device comprising a rinsing device. Furthermore, the device according to this formulation comprises a sample collector which collects the samples dissolved by rinsing.

The rinsing device advantageously makes it possible, on the one hand, to detach a sample from a surface of the module and, on the other hand, not to damage the surface in the process. As a result, the sample can be detached from the surface with as little destruction as possible. In the case of an interface that should be examined for its state of corrosion, it is possible on the one hand to remove corrosion products by rinsing and on the other hand to keep the corrosion system intact. The corrosion system comprises the interface and the corrosion products formed thereon, some of which are securely connected to the interface. For example, the corrosion system thus has regions which, due to corrosion products already formed, are capable of offering protection against progressive corrosion to the base material of the flange and/or of the base body. As a result, the corrosion can be at least slowed down or even completely stopped without adversely affecting the tightness of the interface.

In a first embodiment of the invention, a feed line can be arranged at one end of the rinsing device. For example, the feed line can be connected to a pump or a hand pump, which applies the pressure necessary for rinsing to the rinsing fluid.

In particular, the sample collector can be arranged at the other end of the device, i.e. on the side opposite the feed line.

In a further embodiment of the invention, an opening of the rinsing device can be arranged between the feed line and the sample collector.

In particular, the opening of the rinsing device can be directed in the direction of the feed line. For example, the opening can be oriented at an angle to the feed line such that the rinsing fluid can spray a specific surface of the module for the purpose of collecting the sample. This angle can be in a range from 90° to 180°, preferably in the range from 120° to 160°, particularly preferably in a range from 135° to 155°.

The sample collector can be of elastic form in a further embodiment. Should the device need to be pushed through a constriction, such as a tube or a channel, for example, to the site of sampling, this allows the outer contour of the sample collector to be able to temporarily adapt to the cross section of the constriction. The sample collector can additionally act as a sealing element during the rinsing process, with the sample collector of elastic form being capable of ensuring uniform and complete contact between the sample collector and a surface to be sealed.

Furthermore, the sample collector can be of open-pore form. An open-pore structure allows the collection both of fluids such as the rinsing fluid, for example, and of liquids and/or liquid samples possibly present at the site of the sampling. The open-pore surface is additionally advantageous in that even solid samples adhere more easily to the open-pore surface, and thus the collection of the samples with the sample collector is facilitated.

In addition, the sample collector can comprise a surface for collecting at least a portion of a sample. It may have a geometry that is particularly suitable for collecting the sample, such as a bevel, for example, and/or a special surface that for example acts adhesively in relation to certain samples.

In a further embodiment of the invention, the device can comprise a receptacle for connecting the sample collector to the device. The sample collectors can expediently be renewed with each sampling, and so a simple exchange of the sample collectors is advantageous. The device may for example comprise a mandrel with conical sections or other undercuts. The mandrel facilitates the pushing-on process, with the conical sections advantageously being able to prevent the sample collector from accidentally slipping off, for example when the device is pulled out of a tube or a channel.

In a further embodiment, the device can comprise a stop for positioning the opening of the rinsing device. The stop serves for good repetition accuracy in the alignment of the device with respect to a surface at the site of the sampling, such as an interface of a module, for example. In particular, the stop can be designed to be adjustable, as a result of which a device can be used for sampling different objects.

An arrangement according to the invention having a device for sampling a module for semiconductor technology and a module for semiconductor lithography, with the module comprising a fluid channel and a releasable connecting element for connecting a fluid line to the fluid channel and with an interface being formed between the connecting element and the module, is distinguished in that the device for sampling comprises a rinsing device. In this case, a sample collector of the device is at least partially introduced into the fluid channel, optionally also completely introduced therein, said sample collector being arranged downstream of the rinsing device in the introduction direction.

As already explained further above, the rinsing device allows samples, such as corrosion products, to be detached from the interface in a non-destructive manner.

Furthermore, the device for sampling can be introduced into the connecting element as far as a stop of the device, said connecting element for example being in the form of a flange.

In particular, the stop can define the position of the rinsing device in relation to the interface. This is advantageous in that sampling the interface can be ensured during the introduction of the device even without said interface being seen.

For sampling in the inserted state, an opening of the rinsing device can furthermore be arranged downstream of the interface in the introduction direction. This allows the interface to be sprayed directly with the rinsing fluid even if said interface is arranged downstream of an undercut in the introduction direction.

In particular, the opening of the rinsing device can be oriented in the direction of the interface for sampling purposes. This is advantageous in that the rinsing fluid sprays in the direction of the connecting element, and the risk of the rinsing fluid penetrating into the fluid channel is advantageously reduced. The requirements for the sealing effect of a sample collector of the device can thereby be reduced, whereby the introduction and withdrawal of the device can be significantly simplified.

In a further embodiment, the device can be arranged so as to be rotatable vis-à-vis the connecting element. This allows the interface to be sprayed over the full circumference and thus the best possible sample collection.

In particular, the sample collector of the device can be designed such that, in the inserted state, the sample collector can seal off the fluid channel in the direction of the module interior vis-à-vis a rinsing fluid used during the sampling. The sample collector thus has a dual function, with the second function possibly being that of sealing the fluid channel during the sample collection, whereby penetration of the rinsing fluid into the fluid channel of the module can be prevented.

In addition, the sample collector can be designed such that the sample collector can collect or pick up samples that are dissolved and/or floating in the rinsing fluid, such as corrosion products, for example, during extraction.

In further embodiments, the arrangement may comprise a device according to the embodiments described further above.

A method according to the invention for determining a state of corrosion of an interface between a module of a projection exposure apparatus and a connecting element releasably connected to the module comprises the following method steps:
sampling the interface.
analyzing the sample taken.
determining the state of the interface on the basis of the analysis.

In a first embodiment, the state of the interface can describe a service life of the interface. For example, the service life relates to the remaining duration of safe use of the module in a projection exposure apparatus.

Furthermore, the state of the interface can describe a tightness of the interface. In projection exposure apparatuses operated under predetermined strict boundary conditions, tightness is an important criterion for all fluid-carrying interfaces. In the case of an EUV projection exposure apparatus operated in vacuo, a leak can lead to damage or even to the complete failure of the module and/or of the entire projection exposure apparatus.

In particular, the state of the interface can describe a service life of the interface related to the tightness of the interface. The service life therefore relates to the length of time for which it is still possible to assume that the interface is tight under given boundary conditions.

In a further embodiment, sampling may comprise rinsing the interface, as already explained further above.

Furthermore, the interface can be rinsed in such a way that it only detaches corrosion products from the interface which are already loose and/or liquid and dissolved. The pressure and the jet shape with which the rinsing fluid impinges on the interface is of decisive importance in this context and can ensure that the corrosion system is not damaged.

Furthermore, the corrosion products detached in this way can be collected by a sample collector. In this case, the sample collector is designed such that it can collect both liquid and solid corrosion products.

In a further embodiment, the corrosion products can be analyzed using an EDX method. This is a method known from the prior art and allows accurate analysis of the corrosion products present in the sample.

In particular, the determination of the state of the interface can be based on a comparison of the corrosion products present in the sample. Corrosion can only be determined inadequately by a model, and this can be made even more difficult by many unknown parameters, in particular. Thus, for example, the purity of the fluid used in the fluid channel may be unknown, and/or the storage conditions present should the module be stored may be completely or at least partially unknown. Non-destructive sampling, with non-destructive possibly relating to the tightness of the interface and the corrosion system, is an advantageous method for extending the service life of interfaces.

### BRIEF DESCRIPTION OF THE DRAWINGS

Exemplary embodiments and variants of the invention will be explained in detail below on the basis of the drawing, in which:

FIG. 1 schematically shows a meridional section through a projection exposure apparatus for EUV projection lithography,

FIG. 2 schematically shows a meridional section through a projection exposure apparatus for DUV projection lithography,

FIG. 3 shows a schematic illustration of an exemplary detail of the projection exposure apparatus,

FIG. 4 shows a schematic illustration of an exemplary embodiment of the invention,

FIGS. 5A-C show schematic illustrations for explaining the function and a method according to an embodiment of the invention, in which a sampling device is not yet inserted (FIG. 5A), is inserted (FIG. 5B), and is fully inserted (FIG. 5C) into a fluid channel,

FIGS. 6A-B show further schematic illustrations for explaining the function and a method according to an embodiment of the invention, including starting rinsing (FIG. 6A) and during rinsing (FIG. 6B),

FIGS. 7A-B show further schematic illustrations for explaining the function and a method according to an embodiment of the invention, including after rinsing (FIG. 7A) and during extraction (FIG. 7B) of a rinsing device, and

FIG. 8 shows a flowchart for a method according to an embodiment of the invention.

### DETAILED DESCRIPTION

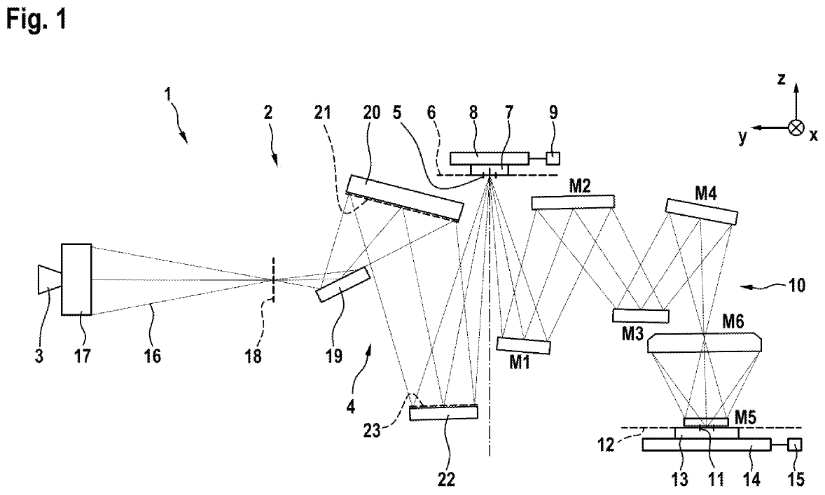

In the following text, the salient constituent parts of a microlithographic projection exposure apparatus 1 are described by way of example initially with reference to FIG. 1. The description of the basic setup of the projection exposure apparatus 1 and the constituent parts thereof are understood here to be non-limiting.

One embodiment of an illumination system 2 of the projection exposure apparatus 1 has, in addition to a radiation source 3, an illumination optics unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable in particular in a scanning direction by way of a reticle displacement drive 9.

A Cartesian xyz-coordinate system is depicted in FIG. 1 for explanation purposes. The x-direction runs perpendicularly to the plane of the drawing extending into the drawing. The y-direction runs horizontally, and the z-direction runs vertically. The scanning direction runs in the y-direction in FIG. 1. The z-direction runs perpendicularly to the object plane 6.

The projection exposure apparatus 1 comprises a projection optics unit 10. The projection optics unit 10 is used to image the object field 5 into an image field 11 in an image plane 12. The image plane 12 extends parallel to the object plane 6. Alternatively, an angle between the object plane 6 and the image plane 12 that differs from 0° is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable in particular in the y-direction by way of a wafer displacement drive 15. The displacement, firstly, of the reticle 7 by way of the reticle displacement drive 9 and, secondly, of the wafer 13 by way of the wafer displacement drive 15 may be synchronized with each other.

The radiation source 3 is an EUV radiation source. The radiation source 3 emits in particular EUV radiation 16, which is also referred to below as used radiation, illumination radiation or illumination light. The used radiation has in particular a wavelength in the range between 5 nm and 30 nm. The radiation source 3 can be a plasma source, for example a laser-produced plasma (LPP) source or a gas discharge-produced plasma (GDPP) source. It may also be a synchrotron-based radiation source. The radiation source 3 can be a free electron laser (FEL).

The illumination radiation 16 emanating from the radiation source 3 is focused by a collector 17. The collector 17 may be a collector having one or more ellipsoidal and/or hyperboloid reflection faces. The illumination radiation 16 may be incident on the at least one reflection surface of the collector 17 with grazing incidence (GI), i.e. at angles of incidence of greater than 45° relative to the direction of the normal to the mirror surface, or with normal incidence (NI), i.e. at angles of incidence of less than 45°. The collector 17 can be structured and/or coated on the one hand for optimizing its reflectivity for the used radiation and on the other hand for suppressing extraneous light.

Downstream of the collector 17, the illumination radiation 16 propagates through an intermediate focus in an intermediate focal plane 18. The intermediate focal plane 18 may constitute a separation between a radiation source module, comprising the radiation source 3 and the collector 17, and the illumination optics unit 4.

The illumination optics unit 4 comprises a deflection mirror 19 and, disposed downstream thereof in the beam path, a first facet mirror 20. The deflection mirror 19 may be a planar deflection mirror or alternatively a mirror with a beam-influencing effect that goes beyond the pure deflection effect. As an alternative or in addition, the deflection mirror 19 can be embodied as a spectral filter that separates a used light wavelength of the illumination radiation 16 from extraneous light of a wavelength deviating therefrom. If the first facet mirror 20 is arranged in a plane of the illumination optics unit 4 that is optically conjugate to the object plane 6 as a field plane, it is also referred to as a field facet mirror. The first facet mirror 20 comprises a multiplicity of individual first facets 21, which are also referred to below as field facets. FIG. 1 shows only some of these facets 21 by way of example.

The first facets 21 may take the form of macroscopic facets, in particular of rectangular facets or of facets with an arcuate or partly circular edge contour. The first facets 21 may take the form of planar facets or alternatively of convexly or concavely curved facets.

As known from DE 10 2008 009 600 A1 for example, the first facets 21 themselves may also be composed in each case of a multiplicity of individual mirrors, in particular a multiplicity of micromirrors. The first facet mirror 20 may in particular take the form of a microelectromechanical system (MEMS system). For details, reference is made to DE 10 2008 009 600 A1.

The illumination radiation 16 travels horizontally, i.e. in the y-direction, between the collector 17 and the deflection mirror 19.

In the beam path of the illumination optics unit 4, a second facet mirror 22 is arranged downstream of the first facet mirror 20. Should the second facet mirror 22 be arranged in a pupil plane of the illumination optics unit 4, this facet mirror is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which can for example have a round, rectangular or else hexagonal boundary, or may alternatively be facets composed of micromirrors. In this regard, reference is likewise made to DE 10 2008 009 600 A1.

The second facets 23 may have plane reflection surfaces or, as an alternative, convexly or concavely curved reflection surfaces.

The illumination optics unit 4 thus forms a doubly faceted system. This basic principle is also referred to as a fly's eye integrator.

It may be advantageous to position the second facet mirror 22 not exactly in a plane optically conjugate to a pupil plane of the projection optics unit 10. In particular, the pupil facet mirror 22 may be tilted relative to a pupil plane of the projection optics unit 10, as described in DE 10 2017 220 586 A1 for example.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing in particular to the imaging of the first facets 21 into the object field 5 can be arranged in the beam path between the second facet mirror 22 and the object field 5. The transfer optics unit may comprise exactly one mirror, or else alternatively two or more mirrors arranged one behind another in the beam path of the illumination optics unit 4. The transfer optics unit can in particular comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the field facet mirror 20 and the pupil facet mirror 22.

In a further embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23, or using the second facets 23 and a transfer optics unit, is generally only approximate imaging.

The projection optics unit 10 comprises a plurality of mirrors Mi numbered consecutively in accordance with their arrangement in the beam path of the projection exposure apparatus 1.

In the example shown in FIG. 1, the projection optics unit 10 comprises six mirrors M1 to M6. Alternatives with four, eight, ten, twelve or any other number of mirrors Mi are also possible. The penultimate mirror M5 and the last mirror M6 each have a through-opening for the illumination radiation 16. The projection optics unit 10 is a doubly obscured optics unit. The projection optics unit 10 has an image-side numerical aperture that is greater than 0.5 and can also be greater than 0.6 and for example can be 0.7 or 0.75.

Reflection surfaces of the mirrors Mi may take the form of free-form surfaces without an axis of rotational symmetry. Alternatively, the reflection surfaces of the mirrors Mi may take the form of aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, in particular with alternating layers of molybdenum and silicon.

The projection optics unit 10 has a large object-image shift in the y-direction between a y-coordinate of a center of the object field 5 and a y-coordinate of the center of the image field 11. This object-image shift in the y-direction may have approximately the same magnitude as a z-distance between the object plane 6 and the image plane 12.

In particular, the projection optics unit 10 may have an anamorphic design. In particular, it has different imaging scales βx, βy in the x- and y-directions. The two imaging scales βx, βy of the projection optics unit 10 are preferably (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction, i.e. in a direction perpendicular to the scanning direction.

The projection optics unit 10 leads to a reduction in size of 8:1 in the y-direction, i.e. in the scanning direction.

Other imaging scales are likewise possible. Imaging scales with the same signs and the same absolute values in the x-and y-directions, for example with absolute values of 0.125 or 0.25, are also possible.

The number of intermediate image planes in the x-direction and in the y-direction in the beam path between the object field 5 and the image field 11 may be the same or may be different, depending on the embodiment of the projection optics unit 10. Examples of projection optics units with different numbers of such intermediate images in the x-and y-directions are known from US 2018/0074303 A1.

One of the pupil facets 23 in each case is assigned to exactly one of the field facets 21 for the purpose of forming a respective illumination channel for illuminating the object field 5. In particular, this may result in illumination according to the Köhler principle. The far field is decomposed into a multiplicity of object fields 5 with the aid of the field facets 21. The field facets 21 generate a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity may be achieved by overlaying different illumination channels.

The illumination of the entrance pupil of the projection optics unit 10 can be defined geometrically by an arrangement of the pupil facets. The intensity distribution in the entrance pupil of the projection optics unit 10 can be set by selecting the illumination channels, in particular the subset of the pupil facets that guide light. This intensity distribution is also referred to as illumination setting.

A likewise preferred pupil uniformity in the region of portions of an illumination pupil of the illumination optics unit 4 that are illuminated in a defined manner can be attained by a redistribution of the illumination channels.

Further aspects and details of the illumination of the object field 5 and in particular of the entrance pupil of the projection optics unit 10 are described below.

The projection optics unit 10 may have a homocentric entrance pupil, in particular. It may be accessible. It may also be inaccessible.

The entrance pupil of the projection optics unit 10 cannot, as a rule, be exactly illuminated using the pupil facet mirror 22. The aperture rays often do not intersect at a single point in the event of imaging by the projection optics unit 10 that telecentrically images the center of the pupil facet mirror 22 onto the wafer 13. However, it is possible to find an area in which the spacing of the aperture rays, which is determined in pairs, becomes minimal. This area represents the entrance pupil or an area conjugate thereto in real space. In particular, this area exhibits a finite curvature.

It may be the case that the projection optics unit 10 has different poses of the entrance pupil for the tangential beam path and for the sagittal beam path. In this case, an imaging element, in particular an optical structural element of the transfer optics unit, should be provided between the second facet mirror 22 and the reticle 7. This optical element may be used to take into account the different pose of the tangential entrance pupil and of the sagittal entrance pupil.

In the arrangement of the components of the illumination optics unit 4 illustrated in FIG. 1, the pupil facet mirror 22 is arranged in an area conjugate to the entrance pupil of the projection optics unit 10. The field facet mirror 20 is tilted with respect to the object plane 6. The first facet mirror 20 is tilted with respect to an arrangement plane defined by the deflection mirror 19.

The first facet mirror 20 is tilted with respect to an arrangement plane defined by the second facet mirror 22.

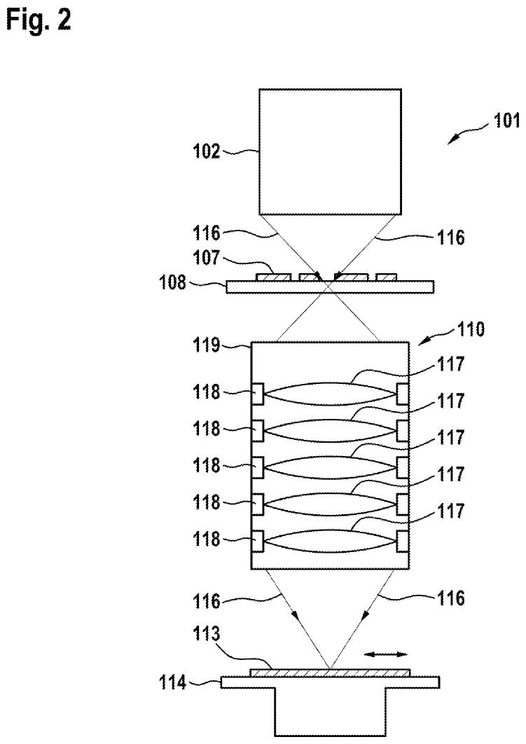

FIG. 2 shows a schematic in meridional section through a further projection exposure apparatus 101 for DUV projection lithography, in which the invention can likewise be employed.

The setup of the projection exposure apparatus 101 and the principle of the imaging are comparable with the setup and procedure described in FIG. 1. Analogous component parts are denoted by a reference sign increased by 100 relative to FIG. 1, i.e. the reference signs in FIG. 2 begin with 101.

By contrast to an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the greater wavelength of the DUV radiation 116, employed as used light, in the range of 100 nm to 300 nm, in particular in the region of 193 nm. The projection exposure apparatus 101 in this case essentially comprises an illumination system 102, a reticle holder 108 for receiving and exactly positioning a reticle 107, which is provided with a structure and is used to determine the later structures on a wafer 113, a wafer holder 114 for holding, moving, and exactly positioning this very wafer 113, and a projection lens 110, with a plurality of optical elements 117 held by way of mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 with optical elements such that the DUV radiation 116 has the desired properties in terms of diameter, polarization, shape of the wavefront and the like when it is incident on the reticle 107.

Apart from the additional use of refractive optical elements 117, such as lens elements, prisms, terminating plates, the setup of the downstream projection optics unit 101 with the lens housing 119 does not differ in principle from the setup described in FIG. 1 and is therefore not described in further detail.

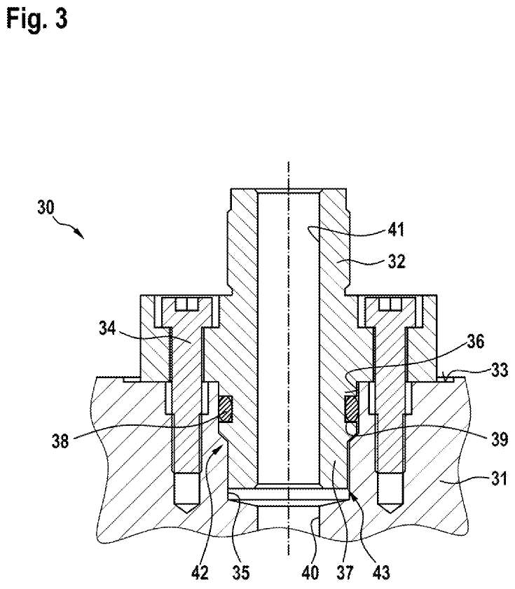

FIG. 3 shows a schematic illustration of a state-of-the-art module 30 having a main body 31, with the main body 31 comprising a fluid channel 40. The module 30 can be designed as a module of a device for semiconductor lithography, such as an illumination system 2, 102 of a projection exposure apparatus 1, 101 explained in FIG. 1 and FIG. 2, for example. As a first portion of an interface 42, the module 30 comprises a flange 32, with which the fluid channel 40 of the main body 31 can be connected, for operation, via a coupling to a tube (not illustrated) for the supply of fluid.

The flange 32 is arranged on a bearing surface 33 on the base body 31 and is connected to the base body 31 by way of screws 34. The flange 32 furthermore has a bore 41 with a diameter that corresponds to the inside diameter of the tube.

The interface 42 furthermore has a cutout 35 in the main body 31 as a portion corresponding to the flange 32, the cutout being conical at least in sections. The cutout furthermore has a cylindrically formed sealing surface 36 in the embodiment illustrated in FIG. 3. The flange 32 in turn comprises a pin 37 whose geometry corresponds to that of the cutout 35, with an O-ring 38 for sealing the flange 32 being arranged in a depression 39 in the region of the pin 37 opposite the sealing surface 36. The cutout 35 in the main body 31 merges into the fluid channel 40.

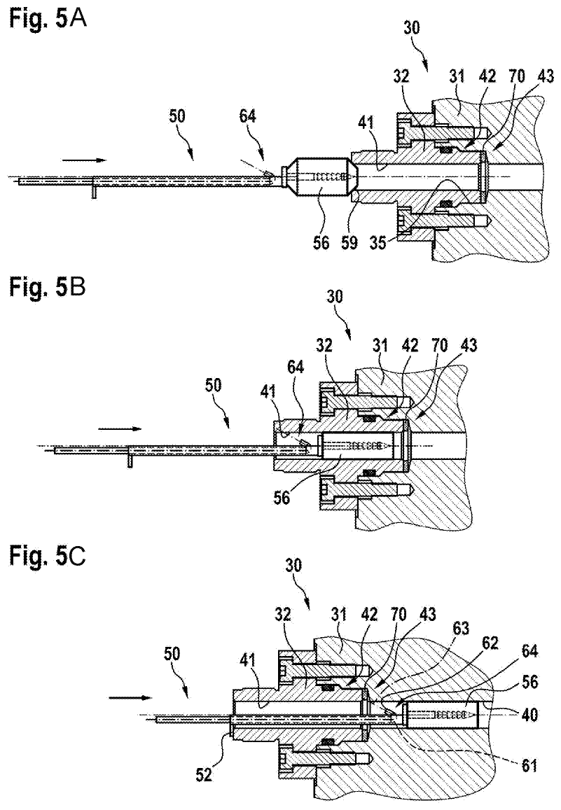

Possible corrosion of the interface 42 is formed in the region between the sealing surface 36 and the opposite region of the pin 37. The corrosion products (not shown) caused in the case of the corrosion are also deposited in the region 43 at the end of the pin 37 (FIG. 5A). Since this region 43 is at least reachable by way of the bore 41, this region 43 is preferably suitable for sampling the interface 42.

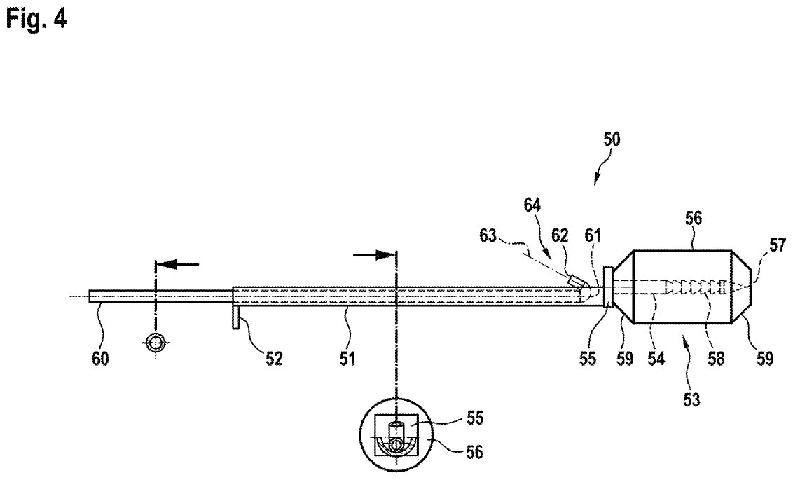

FIG. 4 shows a device 50 according to an embodiment of the invention for sampling the interface 42, especially in the region 43, for determining the state of corrosion of the interface 42. The use of the device 50 is explained in detail in the following figures. The apparatus 50 is designed to extract corrosion products from the interface 42, especially in the region 43 of the sampling (FIG. 3) between the end of the pin 37 and the cutout 35.

The device 50 has a device carrier 51 which is composed of stainless steel or a comparable non-corrosive or slightly corrosive material, which is designed as a half-tube and which, at least in part, can be in the form of a tube. The inside diameter is about 10 mm for ½″ flanges and about 4.5 mm for ¼ flanges.

At one end, the device carrier 51 comprises a stop 52 which defines the penetration depth of the device 50 into the flange 32 (FIG. 3) or the fluid channel 40. Depending on the module 30 to be sampled, the stop 52 is arranged at different positions of the device carrier 51. It is feasible to make the stop 52 adjustable such that the device 50 can be used for sampling different modules 30 or flanges 32. In this case, the stop 52 can for example latch into the positions that correspond to the respective modules 30.

A receptacle 53 for a sample collector 56 is arranged on the side of the device carrier 51 opposite the stop. The receptacle 53 has a connecting element in the form of a mandrel 54 and a stop in the form of a shield 55, up to which stop the sample collector 56 is pushed onto the mandrel 54. This is advantageous in that the sample collector 56 is always arranged at the same position, and the sample collector 56 can be exchanged easily.

The mandrel 54 has a tip 57 for easily pushing the sample collector 56 on. Further along its length, the mandrel 54 has conical sections 58 which further facilitate the action of pushing on the sample collector 56 and advantageously prevent or hinder the sample collector from being pulled off, in particular being pulled off unintentionally. Alternatively, the mandrel 54 can be designed as a screw mandrel or threaded pin in order to be able to secure a sample collector 56 with a female thread or a sample collector 56 with a through-hole by way of a nut and washer.

The sample collector 56 is cylindrical and has bevels 59 on both sides for easier insertion into, or removal out of, the bore 41 in the flange 32 and the fluid channel 40. The embodiment of the sample collector 56 shown in FIG. 4 comprises foam which, on the one hand, is sufficiently elastic to be introduced into the fluid channel 40 through the flange 32 and, on the other hand, ensures sufficient tightness with respect to a rinsing fluid used during the sampling. Furthermore, the rinsing fluid and any corrosion products present can be readily collected by the foam of the sample collector 56 and conveyed out through the bore 41 of the flange 32.

The device 50 furthermore comprises a rinsing device 64 which comprises a feed line in the form of laboratory tubing 60, referred to below as tubing 60, with an inner diameter of 2 mm and an outer diameter of 3 mm. The tubing is guided in the device carrier 51 up to or just in front of the shield 55 of the receptacle 53 and connected to the device carrier 51 (not illustrated). The rinsing device 64 furthermore has a deflection 61 at an angle of 140° at the end of the tubing 60. The direction 63 of an opening 62 of the deflection 61 is directed at the region 43 of the interface 42 (FIG. 3; FIG. 5C) when the device 50 is introduced up to the stop 52. This ensures that the rinsing device 64 directly sprays that region 43 of the interface 42 in which the corrosion products, if present, are expected to occur.

At the other end of the tubing 60, for example, a hand pump or a connector to a pump can be connected, with which the rinsing fluid can be introduced into the device 50.

The following FIGS. 5A-5C, FIGS. 6A, 6B and FIGS. 7A, 7B describe the three phases of the sampling of the interface 42.

FIGS. 5A to 5C describe the introduction of the device 50 into the fluid channel 40 through the bore 41 in the flange 32. In this case, the stop 52 ensures that the opening 62 of the rinsing device 64 is directed at the region 43 of the interface 42 in which possible corrosion products 70 are deposited and/or accumulate.

FIG. 5A shows the state shortly before the introduction of the device 50, in which the bevel 59 of the sample collector 56 bears against the edge of the bore 41 of the flange 32.

FIG. 5B shows the state in which the sample collector 56 made of elastic foam is inserted in a compressed state through the bore 41 in the flange 32. The foam is preferably a foam suitable for sampling, which meets the requirements with regard to outgassing and material composition in semiconductor lithography, in particular in EUV semiconductor lithography. Furthermore, the foam is tear-resistant such that detachment of foam portions during sampling can be avoided.

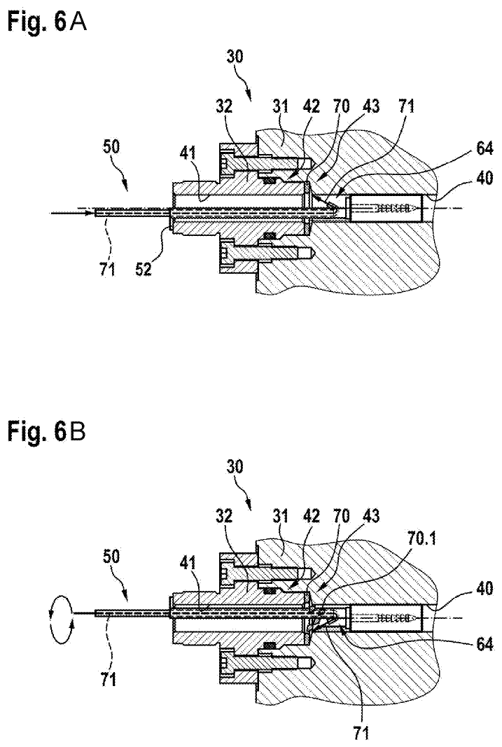

FIG. 5C shows the state in which the device 50 is inserted into the flange 32 as far as the stop 52. The direction 63 of the opening 62 points in the direction of the region 43 in which the corrosion products 70 to be sampled are located. In this state, the sample collector 56 seals off the fluid channel 40 from the rinsing fluid 71 (FIG. 6A).

FIGS. 6A and 6B show the actual sample collection, in which the corrosion products 70 are detached from the region 43 with a rinsing fluid 71. Hard tools such as a hook or scrapers, as used by dentists, for example, are deliberately dispensed with. This ensures that the “corrosion system” is not disturbed as far as possible and that acceleration or accelerated progression of the corrosion due to mechanical damage and/or exposure of surfaces after sampling is precluded. For example, the corrosion system has regions which, due to corrosion products already formed, offer protection against progressive corrosion to the base material of the flange 32 or of the base body 31. As a result, the corrosion can be at least slowed down or even completely stopped without affecting the tightness of the interface 42.

FIG. 6A shows the start of rinsing with the rinsing fluid 71, which, as explained further above, is sprayed with sufficient pressure against the region 43 with the corrosion products 70 by a pump or by the compression of a hand pump. In this case, the pressure is dimensioned such that washing out or detachment of already loose corrosion products 70.1 is ensured, but detachment or mechanical damage of the solid corrosion products 70 is avoided. The corrosion system thus remains intact during sampling.

FIG. 6B shows a state during rinsing, in which the device 50 is rotated in the bore 41 of the flange 32 such that the entire circumference of the region 43 is rinsed with the rinsing fluid 71. It is also possible to identify some detached corrosion products 70.1 which float and/or are dissolved in the rinsing fluid 71.

The rinsing fluid 71 comprises alcohol such as ethanol, for example. Alcohol is inert with respect to the corrosion process, i.e. has no negative influence, i.e., for example, no accelerating influence, on the corrosion even when residues remain. Furthermore, alcohol evaporates rapidly and bonds well with any water still present in the fluid channel 40.

The sample collector 56 aspirates both residual water possibly present in the fluid channel 40 and the rinsing fluid 71.

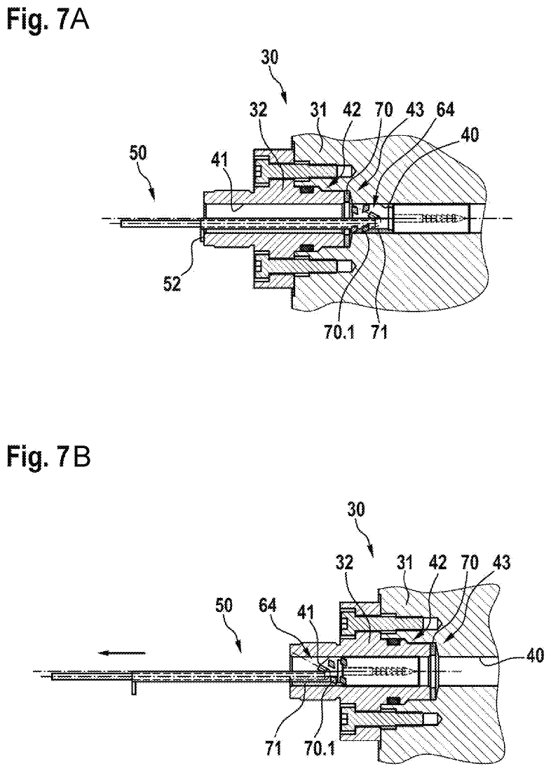

FIGS. 7A and 7B show the extraction of the sample through the bore 41 in the flange 32. The sample comprises the corrosion products 70.1 floating and/or dissolved by the rinsing fluid 71.

FIG. 7A shows the state immediately after rinsing the region 43, with the rinsing fluid 71 collected in the fluid channel 40 and the rinsed-out corrosion products 70.1.

FIG. 7B shows the extraction of the device 50, within the scope of which the sample collector 56 is compressed again. In this case, the foam is designed such that, despite the compression, the rinsing fluid 71 can be completely accommodated by the sample collector 56. The corrosion products 70.1 adhere to the porous surface of the sample collector 56 and are removed with this sample collector 56 from the flange 32. The already dissolved corrosion products 70.1 that remain in the fluid channel 40 during extraction process can be removed at a later stage or removed by flushing the fluid channel 40 in the event of a positive assessment of the interface 42.

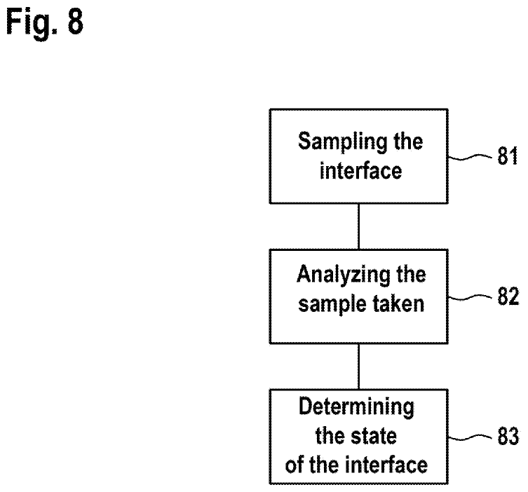

FIG. 8 describes a possible method which makes it possible to determine the state of corrosion of the interface 42 of the module 30.

In a first method step 81, the interface 42 of the module 30 is sampled.

In a second method step 82, the taken sample 70 is analyzed.

In a third method step 83, the state of the interface 42 is determined on the basis of the analysis.

The above description of various embodiments has been given by way of example. From the disclosure given, those skilled in the art will not only understand the present invention and its attendant advantages but will also find apparent various changes and modifications to the structures and methods disclosed. The applicant seeks to cover all such changes and modifications as fall within the spirit and scope of the invention, as defined by the appended claims, and equivalents thereof.

### LIST OF REFERENCE SIGNS

1 Projection exposure apparatus
2 Illumination system
3 Radiation source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Module
31 Base body of the module
32 Flange
33 Bearing surface
34 Screws
35 Cutout in the base body
36 Sealing surfaces of the base body
37 Pin of the flange
38 O-ring
39 Depression in the O-ring
40 Fluid channel
41 Bore in the flange
42 Interface
43 Region of sampling (sampling region)
50 Device
51 Device carrier
52 Stop
53 Receptacle
54 Mandrel
55 Shield
56 Sample collector
57 Tip
58 Conical sections
59 Bevels
60 Laboratory tubing
61 Deflection
62 Deflected opening
63 Opening direction
64 Rinsing device
70, 70.1 Corrosion products
71 Rinsing fluid
81 Method step 1
82 Method step 2
83 Method step 3
101 Projection exposure apparatus
102 Illumination system
107 Reticle
108 Reticle holder
110 Projection optics unit
113 Wafer
114 Wafer holder
116 DUV radiation
117 Optical element
118 Mounts
119 Lens housing
M1-M6 Mirrors

What is claimed is:

1. A sampling device for determining a corrosion state of a module for semiconductor lithography, comprising:
a rinsing device and
a sample collector comprising a surface structured to collect at least a portion of a sample,
wherein an opening of the rinsing device and the sample collector are arranged and configured to insert together at least partially into a fluid channel of the module.

2. The device as claimed in claim 1,
wherein a feed line is arranged at a first end of the rinsing device.

3. The device as claimed in claim 2,
wherein the sample collector is arranged at an end opposing the first end of the rinsing device.

4. The device as claimed in claim 2,
wherein an opening of the rinsing device is arranged between the feed line and the sample collector.

5. The device as claimed in claim 4,
wherein the opening of the rinsing device is directed toward the feed line.

6. The device as claimed in claim 1,
wherein the sample collector is of elastic and/or open-pore form.

7. The device as claimed in claim 1,
wherein the device comprises a receptacle for connecting the sample collector to the device.

8. The device as claimed in claim 4, further comprising:
a stop for positioning the opening of the rinsing device.

9. An arrangement having a device for sampling a module for semiconductor technology and a module for semiconductor lithography, with the module comprising a fluid channel and a releasable connecting element for connecting a fluid line to the fluid channel and with an interface being formed between the connecting element and the module,
wherein the device for sampling comprises a rinsing device, with a sample collector of the device being at least partially introduced into the fluid channel, and wherein the sample collector is arranged downstream of the rinsing device in a direction of the introducing.

10. The arrangement as claimed in claim 9,
wherein the device for sampling is introduced into the connecting element as far as a stop of the device, and with the stop defining a rinsing position of the rinsing device in relation to the interface.

11. The arrangement as claimed in claim 9,
wherein, for sampling in an inserted state, an opening of the rinsing device is arranged downstream of the interface in the direction of the introducing.

12. The arrangement as claimed in claim 11,
wherein, for sampling purposes, the opening of the rinsing device is oriented in the direction of the interface.

13. The arrangement as claimed in claim 9,
wherein the device is configured to rotate vis-à-vis the connecting element.

14. The arrangement as claimed in claim 9,
wherein the sample collector is configured to seal off, in an inserted state, the fluid channel in the direction of the module interior vis-à-vis a rinsing fluid used during the sampling.

15. The arrangement as claimed in claim 9,
wherein the sample collector is configured to collect, during extraction, samples that are dissolved and/or floating in a rinsing fluid.

16. A method for determining a corrosion state of an interface between a module of a projection exposure apparatus and a connecting element releasably connected to the module, comprising:
sampling the interface, comprising taking a sample from the interface,
analyzing the sample taken,
determining a state of the interface based on the analysis.

17. The method as claimed in claim 16,
wherein the state of the interface corresponds to a service life and/or a tightness of the interface.

18. The method as claimed in claim 16,
wherein the state of the interface corresponds to a service life of the interface related to the tightness of the interface.

19. The method as claimed in claim 16,
wherein said sampling comprises rinsing the interface.

20. The method as claimed in claim 19,
wherein the interface is rinsed such that only corrosion products which are already loose and/or liquid and dissolved are detached from the interface.

21. The method as claimed in claim 20, further comprising:
collecting the corrosion products with a sample collector.

22. The method as claimed in claim 20,
wherein said analyzing comprises analyzing the corrosion products using an EDX method.

23. The method as claimed in claim 16,
wherein said determining of the state of the interface comprises comparing the corrosion products present in the sample and determining corrosion products during visual inspections of the interface and performing a visual assessment of the interface.
